(19) United States
(12) Patent Application Publication
(10) Pub. No.: US 2002/0171485 A1
(43) Pub. Date: Nov. 21, 2002

(54) Digitally implemented predistorter control mechanism for linearizing high efficiency RF power amplifiers

(75) Inventor: Armando C. Cova, Sunnyvale, CA (US)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: Spectrian Corporation, Sunnyvale, CA

(21) Appl. No.: 09/954,088

(22) Filed: Sep. 17, 2001

Related U.S. Application Data
(60) Provisional application No. 60/292,190, filed on May 18, 2001.

(51) Int. Cl. H03F 1/26

(52) U.S. Cl. 330/149

(57) ABSTRACT

A digitally-based high distortion rejection scheme for linearizing an RF power amplifier employs a digital signal processor, which executes a first signal processing operator in terms of a digital polynomial-based predistortion function that approximates an inverse of the dynamic memory effects in the nonlinear transfer characteristic of the amplifier, and a second signal processing operator that represents an inverse of static non-linearities in the transfer characteristic of the amplifier. The output of this cascaded filter operation is used to control parameters of a vector modulator in the signal input path to the RF power amplifier. The vector modulator thus predistorts the RF input signal, so as to compensate for dynamic memory effects and static non-linearities in the power amplifier.

### CROSS REFERENCE TO RELATED APPLICATION

The present application claims the benefit of co-pending U.S. Provisional Patent Application, Serial No. 60/292,190 filed May 18, 2001, by Armando Cova, entitled: “Digital Dynamic Predistortion Technique for High Efficiency RF Power Amplifiers,” assigned to the assignee of the present application and the disclosure of which is incorporated herein.

### FIELD OF THE INVENTION

The present invention relates in general to communication systems, and is particularly directed to a flexible, low-cost, digitally-based signal processing for controlling a predistorter used to linearize high-efficiency RF power amplifiers. The digitally based predistorter control mechanism includes a first signal processing operator that compensates for static non-linearities, cascaded with a second polynomial-based signal processing operator that compensates for dynamic memory effects in the amplifier's non-linear transfer characteristic. The output of this digitally implemented cascaded filter operation is converted to an analog control signal for controlling parameters of a vector modulator in the input signal path to the RF power amplifier.

### BACKGROUND OF THE INVENTION

Communication service providers are subject to very strict bandwidth usage spectrum constraints, including technically mandated specifications and regulations imposed by the Federal Communications Commission (FCC). These rules require that sideband spillage, namely the amount of energy spillover outside a licensed band of interest, be sharply attenuated (e.g., on the order of 50 dB). Although these regulations may be easily met for traditional forms of modulation, such as FM, they are difficult to achieve using more contemporary, digitally based modulation formats, such as M-ary modulation.

Attenuating the sidebands sufficiently to meet industry and regulatory-based requirements by such modulation techniques requires very linear signal processing systems and components. Although linear components can be produced at a reasonable cost at the relatively narrow bandwidths (baseband) of telephone networks, linearizing inherently non-linear components such as RF power amplifiers can be prohibitively expensive.

A fundamental difficulty in linearizing RF power amplifiers is the fact that they generate unwanted intermodulation distortion products (IMDs) which manifest themselves as spurious signals in the amplified RF output signal, such as spectral regrowth, or spreading of a compact spectrum into spectral regions that do not appear in the RF input signal. This spectral distortion causes the phase/amplitude of the amplified output signal to depart from the phase/amplitude of the input signal, and may be considered as an incidental (and undesired) amplifier-sourced modulation of the RF input signal.

A brute force and relatively inefficient approach to linearize an RF power amplifier is to build the RF amplifier as a large, high power device, and then operate the amplifier at a very low power level (namely, at only a small percentage of its rated output power), where the RF amplifier's transfer characteristic is substantially linear. An obvious drawback to this approach is the overkill penalty—a costly and large sized RF device.

Other prior art linearization techniques include baseband polar (or Cartesian) feedback, post-amplification, feed-forward correction, and pre-amplification, pre-distortion correction. In the first approach, the output of the RF power amplifier is compared to the input, and a baseband error signal is used to directly modulate the signal which enters the amplifier. In the second approach, error (distortion) present in the RF amplifier's output signal is extracted, amplified to the proper level, and then reinjected (as a complement of the error signal back) into the output path of the amplifier, so that (ideally) the RF amplifier's distortion is effectively canceled.

For an illustration of examples of conventional RF power amplifier linearization schemes, including those referenced above, attention may be directed to the following documentation: U.S. Pat. No. 5,760,646, to D. Belcher et al., entitled “Feed-forward correction loop with adaptive predistortion injection for linearization of RF power amplifier;” an article by W. Bosh et al entitled “Measurement and simulation of memory effects in predistortion linearizers,” IEEE Trans. Microwave Theory and Tech., Vol. 37, No. 12, pp. 1885-1890, 1989; an article by J. Cavers, entitled “Adaptive linearization using a digital predistorter with fast adaptation and low memory requirements,” IEEE Trans. Veh. Technol., Vol. 39, No. 4, pp. 374-382, 1990; U.S. Pat. No. 5,049,832, to J. Cavers, entitled “Amplifier linearization by adaptive predistortion;” an article by A. D′ Andrea et al, entitled “RF power amplifier linearization through amplitude and phase predistortion,” IEEE Trans. Commun., Vol. 44, No. 11, pp. 1477-1484, 1996; an article by M. Faulkner et al entitled “Adaptive linearization using predistortion,” IEEE Trans. Veh. Technol., Vol. 43, No. 2, pp: 323-332, 1994; an article by W. Jeon et al entitled “An adaptive data predistorter for compensation of nonlinear distortion in OFDM systems”, IEEE Trans. Commun., Vol. 45, No. 10, pp. 1167-1171, 1997; and U.S. Pat. No. 5,923,712, to Leyendecker et al., entitled “Method and apparatus for linear transmission by direct inverse modeling.”

### SUMMARY OF THE INVENTION

In accordance with the present invention, distortion at the output of an RF power amplifier is substantially reduced by means of a new and improved digitally implemented predistorter control mechanism, which digitally executes a pair of signal processing operators, respectively associated with dynamic non-linearities and static nonlinear effects in the RF power amplifier's non-linear transfer characteristic. The first signal processing operator executes a set of mathematical expressions representative of the inverse of the amplifier's static non-linearities, while the second signal processing operator subjects the output of the first operator to a polynomial-based filter that compensates for dynamic memory effects in the amplifier's non-linear transfer characteristic. The output of this digital filter is converted to an analog control signal and is used to control the parameters of a vector modulator in the input path to the RF power amplifier.

The predistorter control mechanism of a first embodiment of the invention monitors the RF input to and the RF output from the RF power amplifier, and includes a delay unit to compensate for the time delay required to generate I/Q baseband modulation signals, and provide time-alignment of control and input signals to a predistortion vector modulator installed upstream of the RF power amplifier. The vector modulator modifies the envelope of the delayed and pre-amplified RF signal in accordance with magnitude and phase control signals generated by the cascaded signal processing operators implemented in a digital signal processor (DSP) controller, to which downconverted amplifier RF input and output signals are supplied.

The output of the RF amplifier is coupled to an output assembly which couples a sample of the RF output signal to a distortion detector for application to the DSP controller. The DSP controller sets the location and bandwidth of the sub-bands at which the IMD energy is measured, and employs information provided by the distortion detector to optimize the amplifier's predistorter parameters for maximum IMD rejection in different regions of the transmission band.

The polynomial-based filter of the second signal processing operator is defined in terms of a polynomial function associated with the RF signal's envelope using a set of finite impulse response (FIR) filter stages. The use of a polynomial model-based filter not only reduces memory storage requirements for the DSP, but increases the accuracy of the predistortion estimate. In addition, it obviates the need for interpolation techniques to fill in gaps in a look-up table base scheme, such as that proposed in the above-referenced patent to Leyendecker et al.

The number of terms in the polynomial model may be readily increased or decreased by changing the software employed by the DSP controller. The predistorter parameters in the polynomial model-based filter may be estimated using error minimization routines that employ the baseband I/Q signals for the input RF modulation and baseband I/Q signals for the output RF modulation at the output of the main RF power amplifier. These error minimization estimation routines synchronize the respective baseband I/Q input and output signals using fractional delay interpolators to time-align data.

The predistorter control mechanism both compensates for dynamic non-linearities (memory effects) in the power amplifier and provides larger output distortion suppression than obtainable using traditional static predistortion methods, such as analog workfunctions, polar polynomials, and look-up table-based Cartesian predistortion schemes of the prior art referenced above. Being fully implemented in digital signal processor (DSP) software enables the predistorter control scheme of the invention to provide a level of flexibility that is difficult to achieve in analog predistortion implementations.

Also, in contrast to the digital predistortion scheme described in the above-reference U.S. Pat. No. 5,923,712 (which is intended for narrow-band paging applications), the dynamic predistorter control mechanism of the invention is readily suited for wide-band modulations. The digital predistorter of U.S. Pat. No. 5,923,712, uses a complex-gain look-up table (LUT) to store the predistorter coefficients, whereas the digital predistorter of the present invention employs a polynomial model, which reduces memory storage requirements. The use of a polynomial-based filter for compensating for dynamic memory effects has the additional advantage of increasing the accuracy of predistortion; it also obviates the need for interpolation techniques to fill in gaps in the LUT when there is insufficient training data. Also, being an open-loop linearization system, enables the invention to achieve larger correction bandwidths than those obtained with feedback techniques, such as polar envelope correction.

A second embodiment of the invention uses a baseband digital input supplied from a digital modulator (rather than an RF signal) as its input. This avoids the loss introduced by the delay in the first embodiment. The vector modulator effectively operates as a slow gain/phase actuator in an AGC loop controlled by the DSP controller.

A third embodiment employs a built-in/generic predistortion model. Rather than compute an inverse power amplifier model in accordance with monitored input/output signal samples, as in the first and second embodiments, the DSP controller employs a perturbational algorithm and output distortion estimates provided by the distortion detector to determine the values of the predistortion model parameters. Initial values for the pre-distortion model parameters are loaded into memory before the perturbational algorithm is executed. The third embodiment reduces implementation costs by eliminating amplifier output-monitoring components. However, it has a slower adaptation time and provides a less accurate predistortion, resulting in decreased IMD suppression at the amplifier's output.

### BRIEF DESCRIPTION OF THE DRAWINGS

FIG. 1 diagrammatically illustrates a first embodiment of the digitally implemented polynomial-based RF amplifier predistorter control mechanism of the present invention;

FIG. 2 is a mathematical functional block diagram of a non-limiting example the first and second signal processing operators contained within the predistorter control mechanism of the invention;

FIG. 3 is a spectral diagram illustrating performance improvement provided by the digitally implemented predistorter control mechanism of the present invention;

FIG. 4 diagrammatically illustrates a second embodiment of the invention employing a baseband digital input supplied from a digital modulator; and

FIG. 5 diagrammatically illustrates a third embodiment of the present invention, employing a perturbational algorithm and output distortion estimates provided by a distortion detector to determine predistortion model parameters.

### DETAILED DESCRIPTION

Before detailing the digitally-based predistorter control mechanism of the present invention, it should be observed that the invention resides primarily in an arrangement of conventional RF communication circuits and associated digital signal processing components and attendant supervisory control circuitry, that controls the operations of such circuits and components. As a result, the configuration of these circuits and components and the manner in which they are interfaced with other communication system equipment have, for the most part, been illustrated in the drawings by readily understandable block diagrams, which show only those specific details that are pertinent to the present invention, so as not to obscure the disclosure with details which will be readily apparent to those skilled in the art having the benefit of the description herein. Thus, the block diagram illustrations are primarily intended to show its major components in a convenient functional grouping, whereby the present invention may be more readily understood.

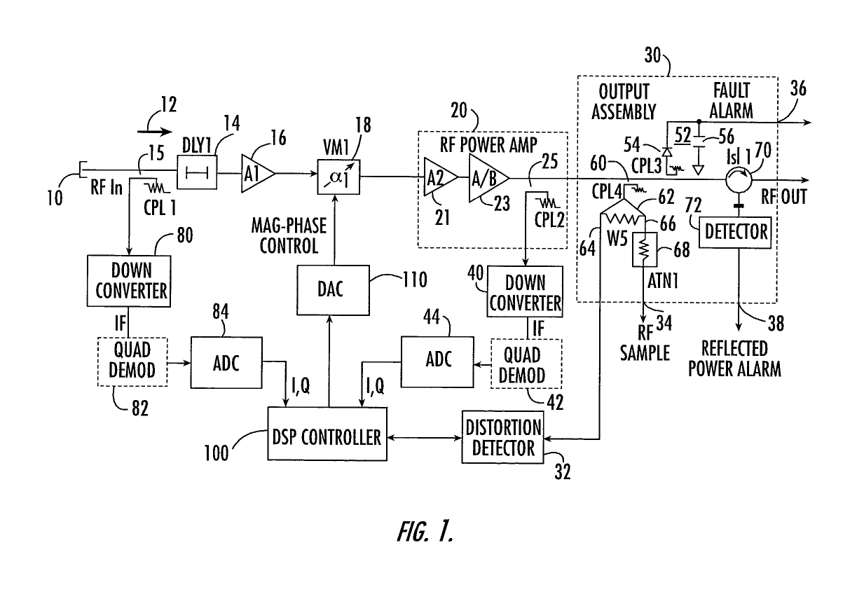

A first embodiment of the predistorter control mechanism of the present invention, in which only the RF input to the RF power amplifier is provided, is shown diagrammatically in FIG. 1 as comprising an input terminal 10 to which an RF input signal RF_{IN} to be amplified is coupled. The RF input signal is coupled over a first predistortion path 12 containing a delay line 14, and a pre-amplifier 16, which is typically comprised of several driver stages, installed upstream of a main RF power amplifier 20 unit. The delay unit compensates for the time delay that occurs in the course of generation of I/Q baseband modulation signals, to be described. This insertion of the input delay line 14 ensures proper operation of the predistorter by time-aligning the control and input signals to a vector modulator 18. The insertion loss of the delay line 14 has a minimum impact on efficiency, since the RF input signal power level is low and the gain of the pre-amplifier 16 can be moderately increased to compensate for the loss in the delay line.

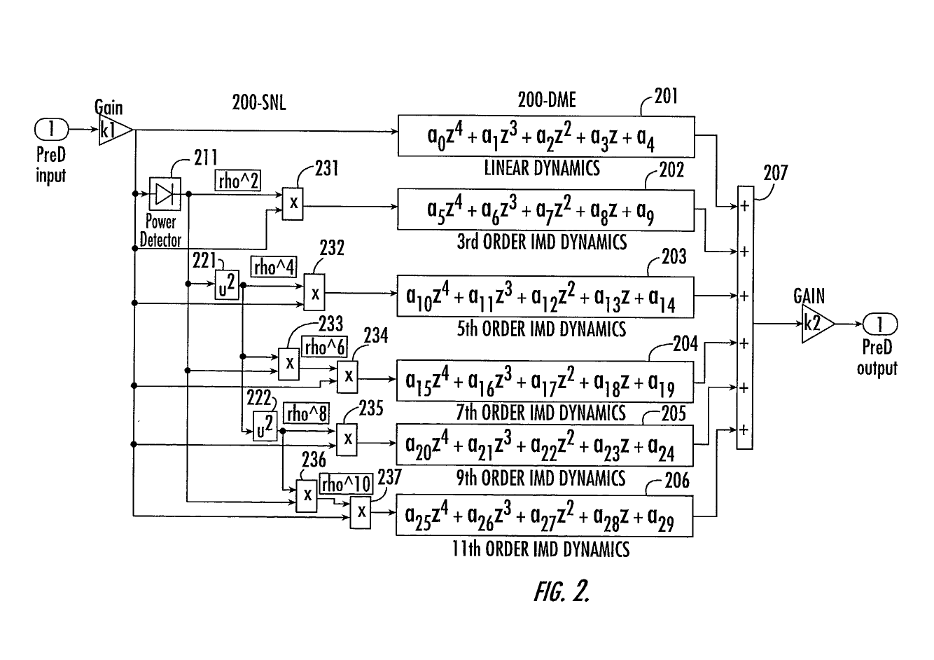

The output of the pre-amplifier 16 is fed to the vector modulator 18, which modifies the envelope of the delayed and pre-amplified RF signal in accordance with magnitude and phase control signals generated by a pair of digitally implemented signal processing operators (to be described below with reference to FIG. 2), that are executed in software employed by a digital signal processor (DSP) controller 100. Coefficients of the predistorter control mechanism generated by the DSP controller 100 are preferably periodically updated to reflect changes in monitored parameters such as the transmitted modulation, temperature, operating conditions, and the like.

The resulting digital control signals produced by the DSP controller 100 executing the cascaded pair of signal processing operators are used to set the phase and amplitude parameters of the vector modulator 18. For this purpose, the digital output of the DSP controller is converted to analog format by a digital-to-analog converter (DAC) 110 and applied to the vector modulator 18. The resulting RF signal as predistorted by the vector modulator 18 is then used to drive the main RF power amplifier unit 20, shown as comprising a preamplifier 21 and a main RF power amplifier 23. The output of the RF power amplifier unit 20 is then coupled to an output assembly 30.

The output assembly 30 couples a sample of the RF output signal to a distortion detector 32, the output of which is fed to the DSP controller 100. As a non-limiting example, the distortion detector may be of the type described in U.S. Pat. No. 6,275,106, entitled: “Spectral Distortion Monitor for Controlling Pre-Distortion and Feed-Forward Linearization of RF Power Amplifier,” assigned to the assignee of the present application and the disclosure of which is incorporated herein. The DSP controller 100 sets the location and bandwidth of the sub-bands at which IMD energy is measured. Using the information provided by the distortion detector 32, the digital predistorter parameters are optimized for maximum IMD rejection in different regions of the transmission band.

The output assembly 30 couples the RF output sample to a sample port 34 and generates fault and reflected power alarms at respective ports 36 and 38. The output assembly 30 includes a directional coupler 50 coupled to the output of the RF power amplifier unit 20, and having its output coupled to a peak detector 52 comprised of a diode 54 and a capacitor 56, which are ported to output fault alarm port 36. A further directional coupler 60 is coupled to a (Wilkinson) splitter 62, having a first output 64 coupled to the distortion detector 32, and a second output 66 coupled through an attenuator 68 to the RF sample output port 34. The output assembly further includes a circulator 70 installed in the RF amplifier output line, and coupled to a detector 72, the output of which is coupled to the reflected power alarm port 38.

The RF amplifier output is further coupled via a directional coupler 25 to a downconverter 40. Downconverter 40 is coupled (via an optional quadrature demodulator 42) to an analog-to-digital converter (ADC) 44, from which respective in-phase (I) and quadrature (Q) baseband RF output channels are provided as monitored inputs to the DSP controller 100.

At the front end of the system, a directional coupler 15 extracts a portion of the RF input signal and couples it to a downconverter 80. The output of the downconverter 80 is coupled (via an optional quadrature demodulator 82) to an ADC 84, from which respective I and Q baseband RF input channels are provided as inputs to the DSP controller 100.

A mathematical functional block diagram of a non-1limiting example of the predistortion control mechanism of the present invention and executable within the DSP controller 100 is diagrammatically illustrated in FIG. 2. As described briefly above, this predistortion control mechanism comprises a first signal processing operator 200-SNL, that is coupled in cascade with a second polynomial-based signal processing operator 200-DME. The first signal processing operator 200-SNL executes a first inverse function f⁻¹ (amp_{RF}) that compensates for the Static Non-Linearity component f(amp_{RF}) in the amplifier's non-linear transfer characteristic. The second polynomial-based signal processing operator 200-DME executes a second inverse function H⁻¹ (jω) that compensates for the Dynamic Memory Effect component H(ω) in the RF amplifier's non-linear transfer characteristic.

The second, polynomial-based signal processing operator 200-DME is shown in FIG. 2 as a set of finite impulse response (FIR) filter stages 201-206. As pointed out above, the polynomial predistortion technique of this invention not only reduces memory storage requirements, but increases the accuracy of the predistortion estimate. In addition, it obviates the need for interpolation techniques to fill in gaps in a look-up table base scheme, such as that proposed in the above-referenced patent to Leyendecker et al. As a non-limiting example, the polynomial-based signal processing operator 200-DME is shown as an eleventh order filter. However, the invention is not limited thereto; the number of terms in the polynomial model may be readily increased/decreased by changing the modeling software employed by the DSP controller 100.

In the eleventh order filter shown, a first order stage 201 executes the linear dynamic filter function a₀z⁴+a₁z³+a₂z²+a₃z+a₄ directly on the RF input signal. The additional polynomial filter stages 202-206, whose outputs are summed at 207 with the first order polynomial stage 201, execute respective sets of third, fifth, seventh, ninth and eleventh order IMD dynamic characteristics, as shown.

The second signal processing operator 200-DME is fed by the front end, first signal processing operator 200-SNL, shown in mathematical block diagram form as including a front end (square law) detector 211 and associated squaring functions 221 and 222, as well as a set of multipliers 231-237 sections 201-206, installed upstream of the respective odd order filter stages of signal processing operator 200-DME.

In accordance with a preferred, but non-limiting example, the parameters of the digitally implemented predistorter control mechanism of the invention are readily estimated using error minimization routines that employ the baseband I/Q signals for the input RF modulation extracted by way of the RF input-extracting directional coupler 15, and baseband I/Q signals for the output RF modulation extracted by way of the directional coupler 25 at the output of the main RF power amplifier unit 20. These error minimization estimation routines synchronize the respective baseband I/Q input and output signals by using fractional delay interpolators to time-align the data.

The adaptive operation of the predistorter is further enhanced by monitoring the output of the distortion detector 32 coupled to splitter 62 in the output assembly 30. As pointed out above, the distortion detector 32 identifies the location of carriers and measures the output IMD energy in different sub-bands. The DSP controller 100 sets the location and (where desired) the bandwidth of the sub-bands at which the IMD energy is measured. Using the information provided by the distortion detector, the digital predistorter parameters can be optimized for maximum IMD rejection in different regions of the transmission band.

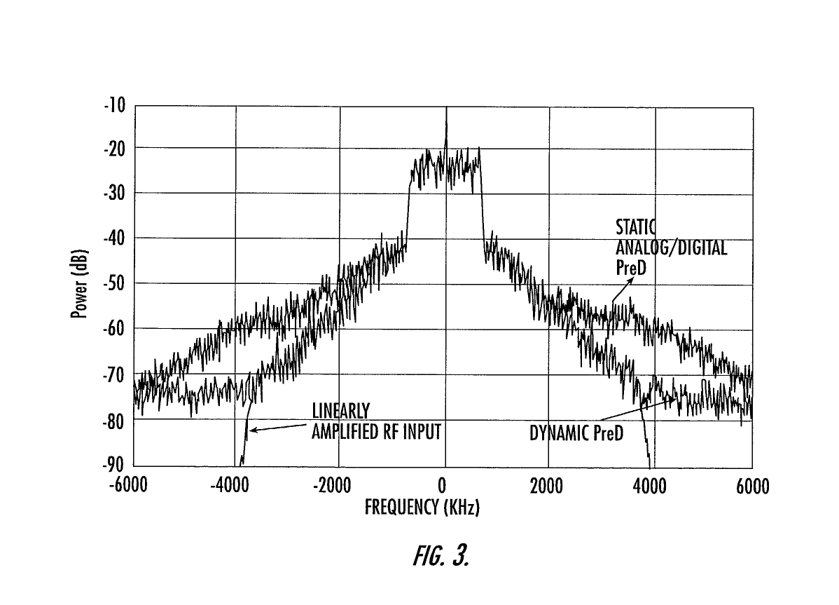

A non-limiting example of performance improvement provided by the digital predistortion mechanism of the present invention is illustrated in the spectral diagram of FIG. 3. As pointed out above, and as shown in FIG. 3, the predistorter control mechanism of the invention achieves larger output distortion suppression than traditional static predistortion methods, such as the analog workfunction, digital polar polynomial, and look-up table-based Cartesian predistortion schemes of the prior art referenced above.

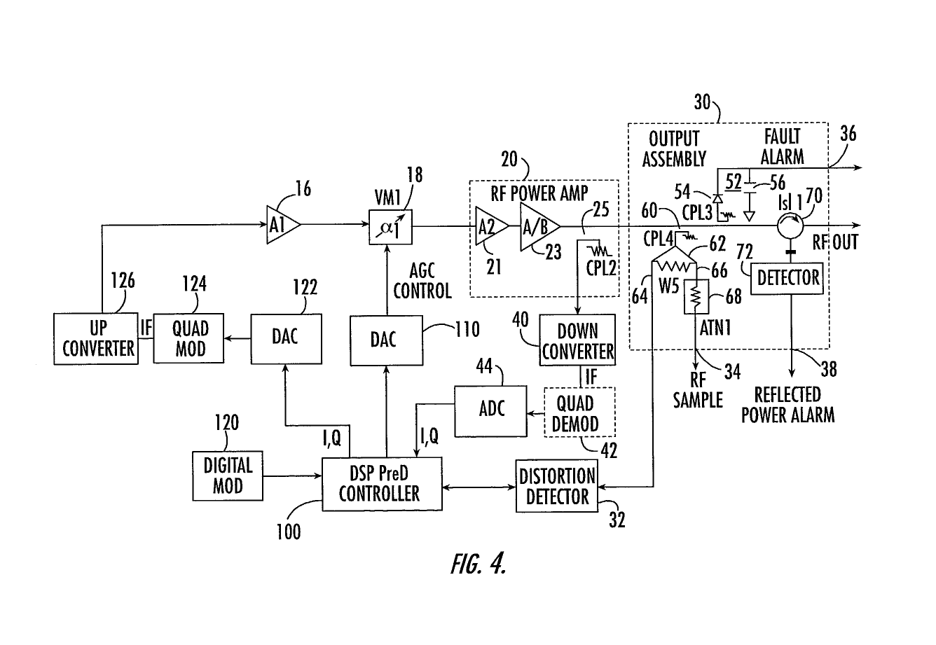

FIG. 4 diagrammatically illustrates a second embodiment of the invention, which employs a baseband digital input supplied from a digital modulator (rather than an RF signal). This second embodiment has the advantage of avoiding the loss introduced by delay line 14 in FIG. 1. In the predistorter control architecture of FIG. 4, a digital modulation signal supplied by a source 120 is predistorted by the DSP controller 100 and then transformed into analog format by a DAC 122. The resulting (I and Q components of the) analog signal are then (quadrature) modulated from baseband to IF by a quadrature modulator 124, and upconverted from IF to RF using an upconverter 126.

The analog RF signal at the output of the upconverter 126 is pre-amplified by pre-amplifier 16 and fed to the vector modulator 18, which effectively operates as a slow gain/phase actuator in an AGC loop controlled by the DSP controller 100. The output of the vector modulator 18 is then used to drive the RF power amplifier unit 20 as in the embodiment of FIG. 1. The remaining components of the embodiment of FIG. 4 function as in FIG. 1.

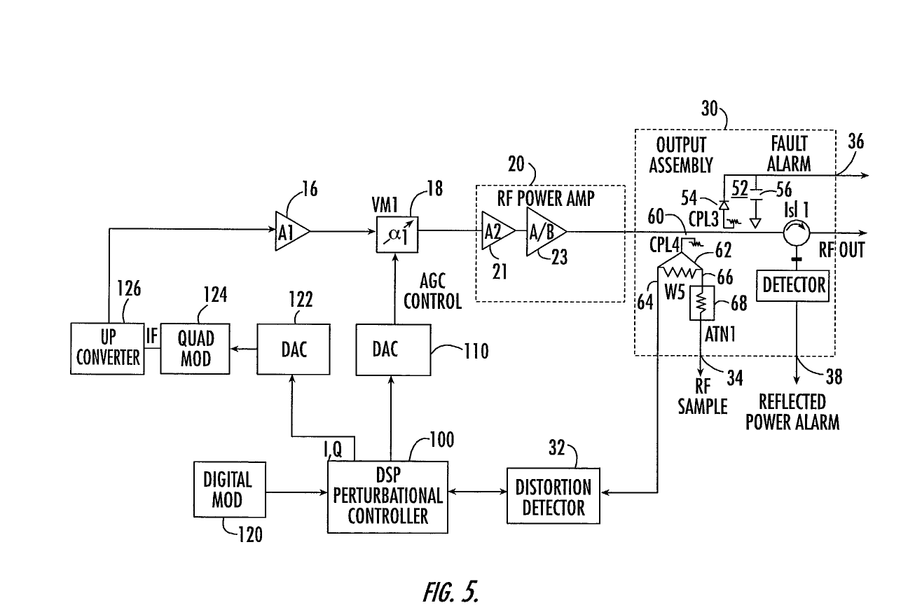

FIG. 5 diagrammatically illustrates a third embodiment of the dynamic predistortion mechanism of the invention intended for predistorting digital inputs, through the use of a built-in or generic predistortion model. In this embodiment, the DSP controller 100 does not compute an inverse power amplifier model in accordance with monitored input/output signal samples, as in the embodiments of FIGS. 1 and 4. Instead, the DSP controller 100 employs a perturbational algorithm and also the output distortion estimates provided by the distortion detector 32 to determine the values of the predistortion model parameters.

Initial values for the pre-distortion filter model parameters are stored in non-volatile random access memory (NVRAM). These parameters are loaded into memory before the perturbational algorithm is executed. The embodiment of FIG. 5 further reduces implementation costs by eliminating the need for the directional coupler 25, downconverter 40, quadrature demodulator 42 and the ADC 44 in the power amplifier's output signal feedback path. It should be noted that, when compared to the embodiments of FIGS. 1 and 4, this implementation has a substantially slower adaptation time and may in some cases provide a less accurate predistortion which reduces the level of IMD suppression at the amplifier's output.

As will be appreciated from the foregoing description, by digitally generating a pair of signal processing operators, respectively associated with dynamic non-linearities and static nonlinear effects in an RF power amplifier's non-linear transfer characteristic, the predistorter control mechanism of the invention enjoys a flexibility that is difficult to achieve in analog predistortion compensation schemes. Being implemented in software enables the invention to be readily modified to compensate for changes in the modulation, temperature, amplifier aging, etc. In addition, the invention does not require special training signals to update its parameters. Also, the use of a polynomial-based filter for compensating for dynamic memory effects reduces memory storage requirements and increases the accuracy of predistortion; it also obviates the need for interpolation techniques to fill in gaps in look-up tables, when there is insufficient training data.

While I have shown and described several embodiments in accordance with the present invention, it is to be understood that the same is not limited thereto but is susceptible to numerous changes and modifications as known to a person skilled in the art, and I therefore do not wish to be limited to the details shown and described herein, but intend to cover all such changes and modifications as are obvious to one of ordinary skill in the art.

What is claimed:

1. An RF power amplifier apparatus comprising:
an RF input port to which an RF input signal is applied;
an RF output port from which an amplified RF output signal is derived;
an RF power amplifier coupled between said RF input port and said RF output port and being operative to amplify an RF signal applied thereto so as to produce said amplified RF output signal;
an RF predistortion unit coupled to a signal path for said RF input signal and being controllably operative to adjust the RF input signal applied to said RF power amplifier; and
a digital signal processor (DSP), which is operative to execute a first signal processing operator in terms of a digital polynomial-based predistortion function that approximates an inverse of the dynamic memory effects in the nonlinear transfer characteristic of said RF power amplifier, said digital polynomial-based predistortion function being used to control said RF predistortion unit in a manner that predistorts said RF input signal to compensate for said dynamic memory effects of the nonlinear transfer characteristic of said RF power amplifier.

2. The RF power amplifier apparatus according to claim 1, wherein said DSP is further operative to execute a second signal processing operator that compensates for static non-linearities in the transfer characteristic of said RF power amplifier.

3. The RF power amplifier apparatus according to claim 2, wherein second signal processing operator provides an output that is coupled as an input to said first signal processing operator.

4. The RF power amplifier apparatus according to claim 1, wherein said digital polynomial-based predistortion function contains a set of finite impulse response (FIR) filter stages that filter the terms of a polynomial function representative of the envelope of the RF signal amplified by said RF amplifier.

5. The RF power amplifier apparatus according to claim 2, wherein said first and second signal processing operators are defined in accordance with said RF input signal and said RF output signal.

6. The RF power amplifier apparatus according to claim 5, wherein said first and second signal processing operators are defined in accordance with baseband in-phase (I) and quadrature (Q) components of said RF input signal and baseband I and Q components of said RF output signal.

7. The RF power amplifier apparatus according to claim 1, further including a distortion detector coupled to the output of said RF power amplifier and being operative to identify carriers and measure the RF amplifier output IMD energy in different sub-bands, said distortion detector being coupled to said DSP controller, which is operative to establish parameters for said RF predistortion unit for maximum IMD rejection in different transmission band regions.

8. The RF power amplifier apparatus according to claim 2, wherein said first and second signal processing operators are defined in accordance with a baseband digital signal that is exclusive of said RF input signal.

9. The RF power amplifier apparatus according to claim 1, wherein said first signal processing operator is defined in accordance with a perturbational algorithm and an estimate of output distortion of said RF power amplifier.

10. A method of reducing the effects of intermodulation distortion of an RF power amplifier comprising the steps of:
(a) coupling an RF input signal to be amplified by said RF power amplifier to an RF predistortion unit that is controllably operative to adjust the RF input signal applied to said RF power amplifier;
(b) generating predistortion model that approximates an inverse of the transfer characteristic of said RF power amplifier, including a first signal processing operator that compensates for static non-linearities, and a second polynomial-based signal processing operator that compensates for dynamic memory effects in the amplifier's non-linear transfer characteristic; and
(c) controlling said RF predistortion unit in accordance with said first and second signal processing operators so as to predistort said RF input signal and compensate for distortion effects of said RF power amplifier.

11. The method according to claim 10, wherein second signal processing operator provides an output coupled as an input to said first signal processing operator.

12. The method according to claim 10, wherein said second signal processing operator contains a set of finite impulse response (FIR) filter stages that filter the terms of a polynomial function representative of the envelope of the RF signal amplified by said RF amplifier.

13. The method according to claim 12, wherein said first and second signal processing operators are defined in accordance with said RF input signal and said RF output signal.

14. The method according to claim 13, wherein said first and second signal processing operators are defined in accordance with baseband in-phase (I) and quadrature (Q) components of said RF input signal and baseband I and Q components of said RF output signal.

15. The method according to claim 10, further including the step of detecting distortion at the output of said RF power amplifier and identifying carriers and measuring the RF amplifier output IMD energy in different sub-bands, and wherein step (c) includes establishing parameters for maximum IMD rejection in different transmission band regions.

16. The method according to claim 10, wherein said first and second signal processing operators are defined in accordance with a baseband digital signal that is exclusive of said RF input signal.

17. The method according to claim 10, wherein said first signal processing operator is defined in accordance with a perturbational algorithm and an estimate of output distortion of said RF power amplifier.

18. An RF power amplifier apparatus comprising:
an RF power amplifier coupled between an RF input port and an RF output port and being operative to amplify an RF signal applied thereto so as to produce an amplified RF output signal;
a vector modulator coupled to receive said RF input signal and being controllably operative to adjust the RF input signal applied to said RF power amplifier; and
a digital signal processor (DSP), which is programmed to execute a first signal processing operator in terms of a digital polynomial-based predistortion function that approximates an inverse of dynamic memory effects in the nonlinear transfer characteristic of said RF power amplifier, said digital polynomial-based predistortion function being used to control said vector modulator in a manner that predistorts said RF input signal to compensate for said dynamic memory effects of the nonlinear transfer characteristic of said RF power amplifier.

19. The RF power amplifier apparatus according to claim 18, wherein said DSP is further operative to execute a second signal processing operator that compensates for static non-linearities in the transfer characteristic of said RF power amplifier.

20. The RF power amplifier apparatus according to claim 19, wherein said first signal processing operator comprises a digital polynomial-based predistortion filter containing a set of finite impulse response (FIR) filter stages configured to filter terms of a polynomial function representative of the envelope of the RF signal amplified by said RF amplifier.
